(19) United States
(12) Patent Application Publication
(10) Pub. No.: US 2009/0236670 A1
(43) Pub. Date: Sep. 24, 2009

(54) Semiconductor Device and a Manufacturing Process Thereof

(75) Inventor: Kuan-Po Hsueh, Sinshih Township (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: HIMAX ANALOGIC, INC., Sinshih Township (TW)

(21) Appl. No.: 12/052,797

(22) Filed: Mar. 21, 2008

(51) Int. Cl. H01L 29/66; H01L 21/336

(52) U.S. Cl. 257/382; 438/197; 257/E29.166; 257/E21.409

(57) ABSTRACT

A semiconductor device has a plurality of drain metal blocks, a plurality of source metal blocks, a plurality of polysilicon strips, a first source metal strip, a first drain metal strip, and a plurality of first conductive wires. Each of the source metal blocks is disposed between two of the drain metal blocks, and at least two of the polysilicon strips are correspondingly disposed across one of the drain metal blocks and one of the source metal blocks. The first source metal strip, in the absence of the polysilicon strips, is electrically connected to some of the source metal blocks. The first drain metal strip, in the absence of the polysilicon strips, is electrically connected to some of the drain metal blocks. The first conductive wires, coupled to the polysilicon strips, form a plurality of grids.

### BACKGROUND

1. Field of Invention

The present invention relates to a semiconductor device. More particularly, the present invention relates to a circuit layout and a manufacturing process of a semiconductor device.

2. Description of Related Art

The physical structure of a semiconductor device determines the performance of the semiconductor. For example, the channel width and the channel length of a semiconductor device affect the current volume of the semiconductor device. Therefore, the layout processes which setup the physical structure of the semiconductor device influence the performance of the semiconductor device.

The power consumption generated by the semiconductor device usually turns out to be thermal energy which might damage the semiconductor device. Therefore, reducing the thermal energy is an important issue in circuit layout. The thermal energy is proportional to the current density, so the circuit layout needs to be designed to reduce the current density.

Generally speaking, the switch consumes more power than other portions in the semiconductor device. Therefore, the structure of the switch becomes the bottleneck of how much power consumption a semiconductor device can endure. In the conventional layout of a switch, a plurality of polysilicon strips are disposed on the substrate to induce a current from the drain to the source. As the total number of the polysilicon strips increases, the current density increases accordingly, which might damage the circuit.

For the foregoing reasons, there is a need for a new semiconductor device which can disperse the current and reduce the current density to prevent the semiconductor device from being damaged by the thermal energy caused by the power consumption.

### SUMMARY

According to one embodiment of the present invention, a semiconductor device has a plurality of drain metal blocks, a plurality of source metal blocks, a plurality of polysilicon strips, a first source metal strip, a first drain metal strip, and a plurality of first conductive wires.

Each of the source metal blocks is disposed between two of the drain metal blocks, and at least two of the polysilicon strips are correspondingly disposed across one of the drain metal blocks and one of the source metal blocks.

The first source metal strip, in the absence of the polysilicon strips, is electrically connected to some of the source metal blocks. The first drain metal strip, in the absence of the polysilicon strips, is electrically connected to some of the drain metal blocks. The first conductive wires, coupled to the polysilicon strips, form a plurality of grids.

According to another embodiment of the present invention, a manufacturing process of a semiconductor device is disclosed. In this process, a plurality of polysilicon strips are formed first. Next, a dielectric layer over the polysilicon strips is formed. Then a source metal layer and a drain metal layer are formed. The source metal layer and the drain metal layer are in contact with a source and a drain on the substrate. Next, a plurality of first bump wires are coupled to the drain metal layer. Both ends of each first bump wire are coupled to the drain metal layer. After that, a plurality of second bump wires are coupled to the source metal layer. Both ends of each second bump wire are coupled to the source metal layer.

It is to be understood that both the foregoing general description and the following detailed description are by examples, and are intended to provide further explanation of the invention as claimed.

### BRIEF DESCRIPTION OF THE DRAWINGS

These and other features, aspects, and advantages of the present invention will become better understood with regard to the following description, appended claims, and accompanying drawings where:

FIG. 1 shows a physical structure of a semiconductor device according to one embodiment of the present invention; and

FIG. 2 shows the manufacturing method of a semiconductor device according to one embodiment of present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

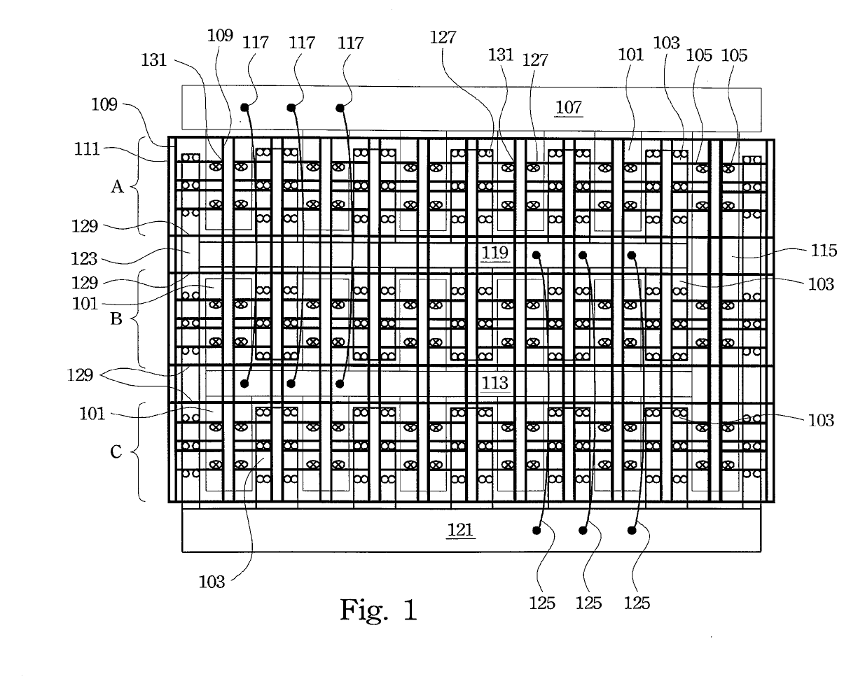

FIG. 1 shows a physical structure of a semiconductor device according to one embodiment of the present invention. The semiconductor device, such as transistors of a switch, includes the drain metal blocks 101, the source metal blocks 103, and the polysilicon strips 105. Each of the source metal blocks 103 is disposed between two of the drain metal blocks 101. At least two of the polysilicon strips 105 are correspondingly disposed across one of the drain metal blocks 101 and one of the source metal blocks 103. Contacts 127 are disposed on the drain metal blocks 101 and the source metal blocks 103. The polysilicon strips 105 and the contacts 127 enable the current to flow between the drain metal blocks 101 and the source metal blocks 103.

The semiconductor device further includes the first source metal strip 119, the second source metal strip 121 and the third source metal strip 123. The second source metal strip 121 is wider than 65 um in order to connect to a bonding wire to receive the source voltage. The first source metal strip 119, in the absence of polysilicon strips, is electrically connected to some of the source metal blocks 103 to collect the current from the source metal blocks 103. The third source metal strip 123 is electrically connected to the first source metal strip 119 and the second source metal strip 121, in which the source voltage can be delivered from the second source metal strip 121 to the first source metal strip 119, and the current can flow from the source metal blocks 103 to the second source metal strip 121.

As a result of this kind of circuit layout, the source metal blocks 103 are 25 divided into three parts, shown in part A, part B and part C; the current is also divided into three parts, too. In addition, several bump wires 125, made of aurum (Au), aluminum (Al), platinum (Pt), or stannum (Sn), are electrically connected to the first source metal strip 119 and the second source metal strip 121 to disperse the current which flows form the first source metal strip 119 to the second source metal strip 121. Therefore, the current is divided as several divisions, such that the current density is reduced, which prevents the semiconductor device from been damaged.

The second drain metal strip 107, used for receiving the drain voltage, is wider than 65 um for a bonding wire disposing on it. For delivering the drain voltage to drain metal blocks 101, some of the drain metal blocks 101 are electrically connected to the second drain metal strip 107 directly; and other drain metal blocks 101 are indirectly electrically connected to the second drain metal strip 107 via the first drain metal strip 113 and the third drain metal strip 115. As a result, the drain metal blocks 101 are divided as three parts, too, so the current is also divided to three parts, shown as part A, part B, and part C, which reduce the current density.

In addition, the first bump wires 117, made of aurum (Au), aluminum (Al), platinum (Pt), or stannum (Sn), are electrically connected to the first drain metal strip 113 and the second drain metal strip 107 for dispersing the current which delivers form the second drain metal strip 107 to the first drain metal strip 113. In other words, the drain current is also divided as several parts, and the current density is reduced accordingly, which prevents the semiconductor device from been damaged.

To connect all the gates of the transistors, the first conductive wires 109 are coupled to the polysilicon strips 105 via contacts 131, and grids are formed as a result of the disposing of the first conductive wires 109 and the polysilicon strips 105. The polysilicon strips 105 and adjacent first conductive wires 109 forms an H shape. The second conductive wire 111 is electrically connected to the first conductive wires 109, and the third conductive wires 129 are coupled to the first conductive wires 109 and the second conductive wire 111, for applying the gate voltage to the first conductive wires 109 thoroughly.

With the first conductive wires 109 and the second conductive wire 111 added, the gate voltage can be delivered to the polysilicon strips 105 more uniformly, and the polysilicon strips 105 can receive the gate voltage or other signals at nearly the same time, which makes the current distribute more uniformly.

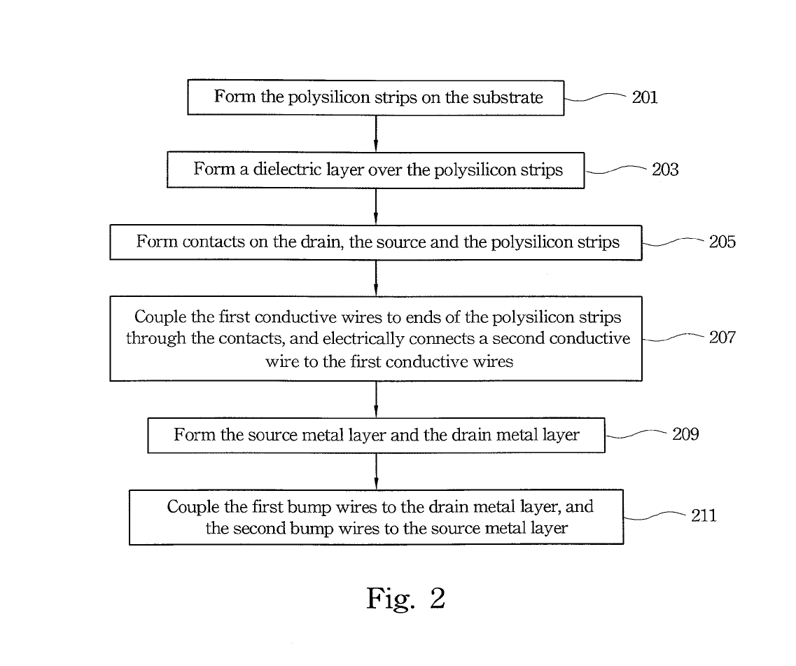

Please refer to both FIG. 1 and FIG. 2. FIG. 2 shows the manufacturing process of a semiconductor device according to one embodiment of the present invention. While manufacturing the semiconductor device described above, such as transistors in a switch, polysilicon strips 105 are first formed over the SIO² (arbitrarily form the WSi^{x} with the polysilicon strips 105) on the substrate (step 201). Then, the dielectric layers, such as Boro Phospho Silicate Glass, are formed over the polysilicon strips (step 203).

Next, contacts 127 are formed on the drain and the source, and the contacts 131 are formed on the polysilicon strips (step 205), in which at least two of the polysilicon strips 105 are disposed between two of the contacts 127. After step 205, couple the first conductive wires 109 to the ends of the polysilicon strips through the contacts 131, and electrically connect a second conductive wire 111 to the first conductive wires 109 (step 207).

After the contacts 127 and the contacts 131 have been formed, form the source metal layer and the drain metal layer (step 209). The source metal layer and the drain metal layer include the source metal blocks 103, the first source metal strip 119, the second source metal strip 121, the third source metal strip 123, the drain metal blocks 101, the first drain metal strip 113, the second drain metal strip 107, and the third drain metal strip 115.

In addition, the first bump wires 117 and the second bump wires 125 are coupled to the drain metal layer and the source metal layer (step 211). Each of the first bump wires 117 and the second bump wire 125 has both ends coupled to the drain metal layer or the source metal layer.

According to the above embodiment, the current has been divided into three parts by above disposing of the drain metal and the source metal, and bump wires have been added to couple to the source metal and the drain metal to further reduce the current density. Because the polysilicon strips and adjacent first conductive wires forms an H shape, the signals, such as gate voltage, can arrive at each polysilicon strip at nearly the same time, which makes the current distribution more uniform.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A semiconductor device, comprising:
a plurality of drain metal blocks;
a plurality of source metal blocks, each disposed between two of the drain metal blocks;
a plurality of polysilicon strips, wherein at least two of the polysilicon strips correspondingly disposed across one of the drain metal blocks and one of the source metal blocks;
a first source metal strip, electrically connected to some of the source metal blocks, in the absence of the polysilicon strips;
a first drain metal strip, electrically connected to some of the drain metal blocks, in the absence of the polysilicon strips;
a plurality of first conductive wires, coupled to the polysilicon strips, wherein the first conductive wires forms a plurality of grids;
a second drain metal strip electrically connected to the drain metal blocks which are not directly connected to the first drain metal strip, for receiving a drain voltage, wherein the second drain metal strip is a straight strip; and
a third drain metal strip electrically connected to the first drain metal strip and the second drain metal strip, for delivering the drain voltage to the first drain metal strip.

2. The semiconductor device as claimed in claim 1, wherein each of the polysilicon strip and the adjacent first conductive wires forms a H shape.

3. The semiconductor device as claimed in claim 1, further comprising a second conductive wire electrically connected to the first conductive wires, wherein the second conductive wire is used for receiving a gate voltage.

4. The semiconductor device as claimed in claim 3, further comprising a plurality of third conductive wires coupled to the first conductive wires and the second conductive wire, wherein the third conductive wires are used for applying the gate voltage to the first conductive wires.

5. (canceled)

6. The semiconductor device as claimed in claim 1, wherein the second drain metal strip is wider than 65 um.

7. The semiconductor device as claimed in claim 1, further comprising a plurality of first bump wires, electrically connected to the first drain metal strip and the second drain metal strip, for delivering the drain voltage form the second drain metal strip to the first drain metal strip.

8. The semiconductor device as claimed in claim 7, wherein the first bump wires are made of Au, AL, Pt, Sn.

9. The semiconductor device as claimed in claim 1, further comprising:
a second source metal strip; and
a plurality of second bump wires, electrically connected to the second source metal strip and the first source metal strip, for delivering the current between the first source metal strip and the second source metal strip.

10. The semiconductor device as claimed in claim 9, wherein the second bump wires are made of Au, AL, Pt, Sn.

11. The semiconductor device as claimed in claim 9, wherein the second source metal strip is wider than 65 um.

12. The semiconductor device as claimed in claim 1, further comprising a plurality of contacts, disposed on the drain metal blocks, wherein at least two of the polysilicon strips are disposed between two of the contacts.

13-16. (canceled)
